(19) United States
(12) Patent Application Publication
(10) Pub. No.: US 2007/0215463 A1
(43) Pub. Date: Sep. 20, 2007

(54) PRE-CONDITIONING A SPUTTERING TARGET PRIOR TO SPUTTERING

(75) Inventor: VIJAY D. PARKHE, San Jose, CA (US)

Correspondence Address: JANAH & ASSOCIATES, P.C., 650 DELANCEY STREET, SUITE 106, SAN FRANCISCO, CA, 94107, US

(73) Assignee: Applied Materials, Inc.

(21) Appl. No.: 11/685,151

(22) Filed: Mar. 12, 2007

Related U.S. Application Data
(60) Provisional application No. 60/782,740, filed on Mar. 14, 2006.

(51) Int. Cl. C23C 14/00; B01D 35/06

(52) U.S. Cl. 204/298.12; 204/640

(57) ABSTRACT

A sputtering target is pre-conditioned prior to use of the target in a sputtering process by removing a damaged surface layer of a sputtering surface of the target. In one version, the sputtering surface of the sputtering target is lapped to remove a thickness of at least about 25 microns to obtain a sputtering surface having a surface roughness average of from about 4 to about 32 microinches. In another version, an acidic etchant is used to remove the layer. In yet another version, the damaged surface layer is annealed by heating the surface.

### RELATED APPLICATION

This application is filed as a non-provisional application and claims priority from provisional application No. 60/782,740 which was filed on Mar. 14, 2006 and which is incorporated by reference herein in its entirety.

### BACKGROUND

Embodiments of the present invention relate to pre-conditioning a sputtering target prior to its use in a sputtering process.

A sputtering chamber is used to sputter deposit material onto a substrate, such as for example, a semiconductor wafer or display, in the fabrication of electronic circuits and displays. The sputtering chamber uses a sputtering target mounted in the chamber. The target comprises a sputtering surface composed of sputtering material which may be a metal, such as for example, aluminum, copper, tantalum, titanium or tungsten. Compounds of a sputtering material can also be deposited in the chamber, such as for example, tantalum nitride, titanium nitride and tungsten nitride. Typically, the chamber comprises an enclosure which encloses a process zone into which a process gas is introduced, a gas energizer to energize the process gas to form a plasma, and an exhaust port to exhaust and control the pressure of gas in the chamber. In the sputtering processes, the sputtering target is bombarded by energetic plasma species, causing material to be sputtered off the target and deposit onto the substrate.

However, the fabrication process used to form the sputtering target often creates a damaged surface layer of the target that produces undesirable or inconsistent sputtering properties. Typically, a sputtering target is machined to a disc shape by mechanical processes such as lathing and milling. These machining processes produce shearing forces on the surface of the target which can plastically deform, and create other defects in, the surface grains. In plastic deformation, adjacent planes of atoms within each grain slip over one another resulting in a permanent lateral displacement of the lattice planes relative to each another to produce a smeared grain structure. Typically, the damaged surface layer also has a higher dislocation density. In sputtering processes, the grains defects in the sputtering target affect the distribution of target material ejected from the target. Damaged grains or surface layers with higher dislocation densities result in variable and non-uniform sputtering properties across the target surface. For example, the damaged surface layer can cause the sputtering rate from the sputtering target to vary until the surface grains are sputtered off from the target. This results in deposition of a non-uniform thicknesses of sputtered material on different substrates of a processed batch of substrates, non-uniform deposition across the surface of a single substrate. Another problem arises when the sputtering surface of the target reacts with the ambient or external environment to form an undesirable surface layer which affects its sputtering properties. For example, the sputtering target material can react with oxygen in ambient air to form an oxidized surface layer.

To remove the undesirable damaged surface layer of a sputtering target, a burn-in process step is typically performed after the sputtering target is mounted in a sputtering chamber. In the burn-in process, the sputtering surface of the target is exposed to plasma to sputter-off the undesirable surface layer of the target. The target burn-in step can be performed, for example, for 150 kW-hours of plasma to remove a sufficient thickness of the target surface to provide more uniform sputtering rates when the target is subsequently used in production processes. However, the target burn-in process takes time to complete, during which the sputtering chamber cannot be used for production. This ineffective utilization of the sputtering chamber increases processing costs. Thus, it is desirable to have a process for removing the damaged surface layer on a sputtering target that is more efficient and does not tie-up use of the sputtering chamber for an extended target burn-in time.

### DRAWINGS

These features, aspects, and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1 is a sectional side view of an embodiment of a sputtering target having a sputtering surface;

FIG. 2A is a partial sectional side view of an embodiment of a sputtering target having a sputtering surface with a damaged surface layer;

FIG. 2B is a partial sectional side view of the sputtering target of FIG. 2A after removal of the damaged surface layer from the sputtering surface;

FIG. 3 is a graph of an X-ray diffraction pattern of the sputtering surface of a sputtering target showing the X-ray diffraction peaks obtained for varying diffraction angles;

FIG. 4A is a schematic of an embodiment of a polishing apparatus for polishing the sputtering surface of a sputtering target;

FIG. 4B is a schematic of another embodiment of a polishing apparatus for polishing the sputtering surface of the sputtering target;

FIG. 5 is a partial sectional side view of an embodiment of an acidic etchant tank and a fixture for holding the sputtering target in the tank;

FIG. 6 is a schematic view of a laser beam apparatus for laser treating a sputtering surface of a sputtering target;

FIG. 7 is a schematic of an electric discharge machining apparatus;

FIG. 8 is a sectional side view of an embodiment of a sputtering chamber capable of using the sputtering target; and

FIG. 9 is a schematic diagram of an electropolishing apparatus for electropolishing a sputtering target.

### DESCRIPTION

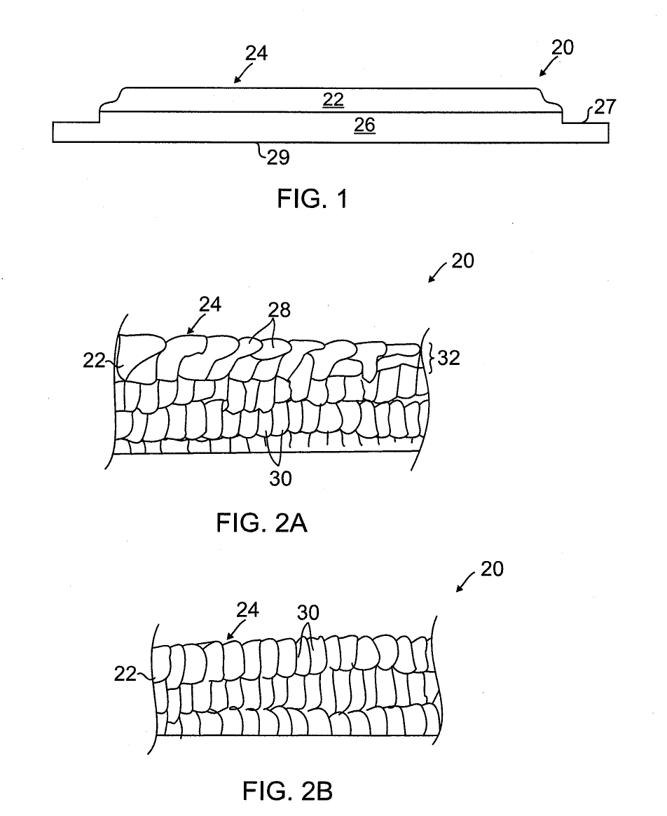

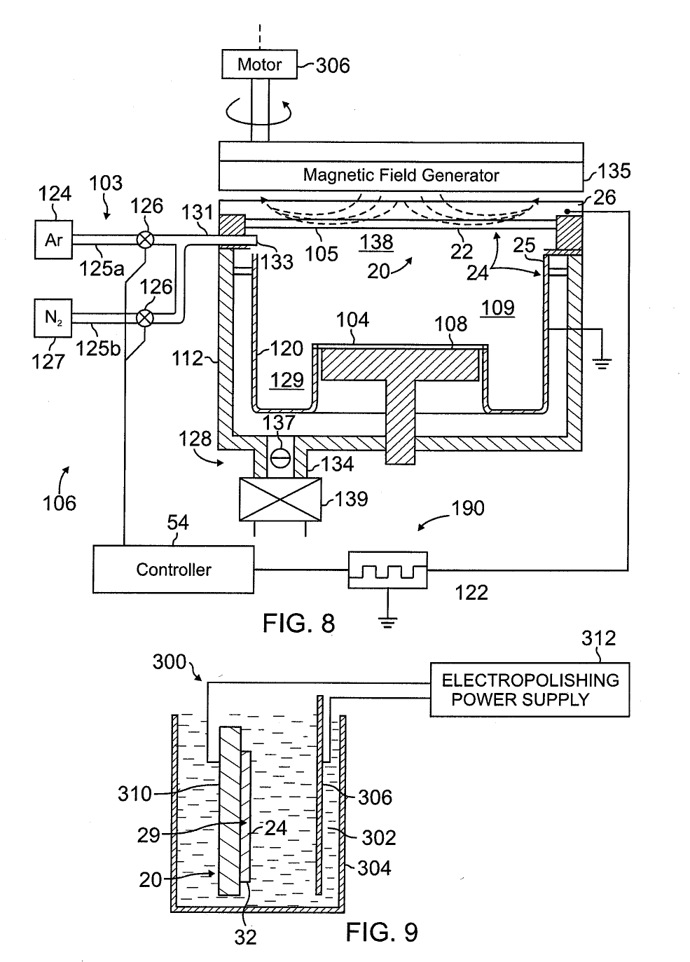

An embodiment of a sputtering target 20 capable of sputter depositing material on a substrate 104 is shown in FIG. 1. The target 20 comprises a sputtering plate 22 composed of sputtering material, which can comprise a metal, such as for example at least one of titanium, tantalum, tungsten, or an alloy containing one of those elements or other metals. The sputtering plate 22 comprises a sputtering surface 24 from which material can be removed to deposit material on a substrate 104, for example, by sputtering the sputtering surface 24 with an energized gas. The sputtering plate 22 can be fabricated by a suitable method, including for example, a chemical vapor deposition, casting, physical vapor deposition, electroplating, hot isostatic pressing, and other methods. For processing of circular semiconducting wafers, typically, the sputtering plate 22 is disc-shaped. The sputtering plate 22 can also have with a diameter of from about 200 mm to about 500 mm, and a thickness of from about 2.5 to about 25 mm. However, the sputtering target 20 is not limited to a particular geometrical configuration, and can have other shapes which depend on the shape of the substrate 104 or other sizes. For example, the sputtering target 20 can be rectangular or square shaped for processing of displays and rectangular substrates. In another version, the sputtering target 20 also includes an annular coil 25 (as shown in FIG. 8) which is mounted on the sidewall of the chamber 106 about the circumference of the sputtering plate 22 mounted on the ceiling of the chamber 106. Both the ceiling mounted sputtering plate 22 and the side mounted annular coil 25 comprise sputtering surfaces 24, and both serve as the sputtering target 20 in this version.

In one version, the sputtering target 20 comprises a sputtering plate 22 mounted on a backing plate 26 which serves to support the sputtering plate 22 on the ceiling of a sputtering chamber 106. The backing plate 26 is typically composed of a metal such as copper, or a metal alloy such as a copper-zinc alloy, which provides good thermal conduction to allow cooling of the sputtering plate 22 during a sputtering process. The backing plate 26 comprises a peripheral ledge 27 which rests on an annular ring in the sputtering chamber 106. The backside 29 of the backing plate 26 can also contact a heat exchanger in the chamber to further cool the sputtering plate 22 during sputter processing. The sputtering plate 22 is typically diffusion bonded to the backing plate 26. The side mounted annular coil 25 can also have a sputtering surface 24 to provide sputtered species which deposit about the peripheral regions of the substrate 104 to provide better, or more uniform, sputtering material.

The processing of substrates 104 with the sputtering target 20 (which can be the sputtering plate 22 or the annular coil 25) is improved by pre-conditioning the target 20 by removing a thickness of the sputtering surface 22 comprising a damaged surface layer 32. For example, in some targets, the damaged surface layer 32 is primarily composed of plastically deformed grains 28 which form a “smeared” surface grain structure along the sputtering surface 24 as shown in FIG. 2A. Under the smeared grain structure 28 remain un-deformed grains 30 which typically provide better or more uniform sputtering properties. The damaged surface layer 32 can also have, or alternatively only have, a high dislocation density. The thickness of the damaged surface layer 32 on the surface of the target 20 depends on grain size of the target, and is typically at least about 25 microns, and more typically from about 50 to about 300 microns. The sputtering surface 24 can also have a metal oxide or other layer (not shown) formed on the exposed surface.

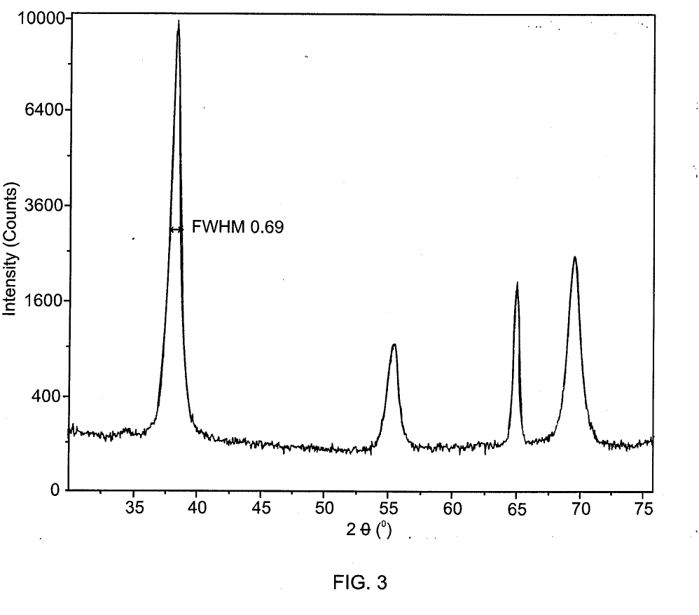

FIG. 3 is a graph of an X-ray diffraction pattern of the sputtering surface 24 of a sputtering target 20 showing X-ray diffraction peaks as a function of the diffraction angle. When the damaged surface layer 32 comprises grains 28 which are plastically deformed, the distance between the lattice planes varies from one grain to another and causes peak broadening. The FWHM (full width at half maxima) of the diffraction peak at a 2Θ angle of about (38°) is a measure of the non-uniform microstrain that results from the plastic deformation of the lattice planes. A larger value of FWHM indicates a higher strain level and a higher degree of variation of the position of the lattice planes of the smeared grains 28. After initial machining, it is seen that the FWHM of the sputtering surface is about 0.69 as shown in FIG. 3. When the damaged surface layer 32 is substantially removed from the sputtering surface 24, as shown in FIG. 2B, the underlying un-deformed grains 30 are exposed on the sputtering surface 24, and the FWHM of the diffraction peak is reduced to less than about 0.4.

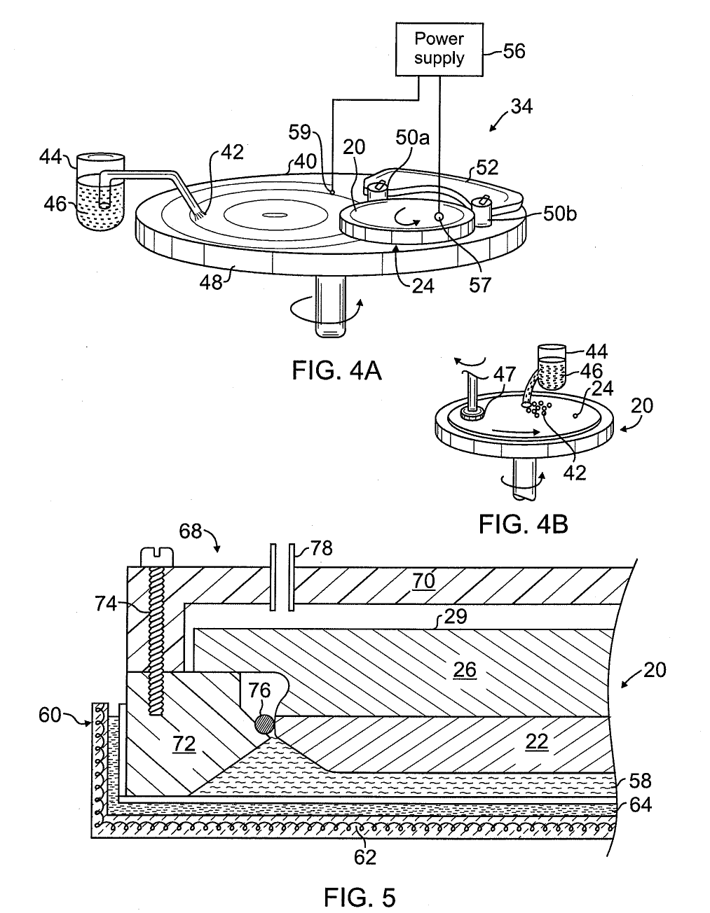

In one version of the present process, after the shape of the target is machined on a lathe, the sputtering surface 24 of the sputtering plate 22 is polished by a polishing process in a polishing apparatus 34 to remove substantially all the damaged surface layer 32 at the sputtering surface 24 and expose the underlying un-deformed grains 30 or grains having a lower dislocation density, as shown in FIG. 2B. In one version of this process, the target 20 is held against a lapping wheel 40, while a polishing slurry 42 is applied to the wheel 40 from a slurry dispenser 44 containing a slurry supply 46, as shown in FIG. 4A. The wheel 40 and target 20 are rotated against each other to abrade away the exposed surface 24 of the sputtering plate 22. The polishing process is typically a low-pressure, low-speed operation to achieve a better surface finish polish of the sputtering surface 24. The slurry comprises abrasive particles having a predefined range of particle sizes and hardness. The sputtering surface 24 is polished to remove a thickness of the surface 24 which is sufficient to remove the plastically deformed grains and any surface oxidation layer. For example, the sputtering surface 24 of the sputtering target 20 can be polished to remove the layer 32 which can have a thickness of at least about 25 microns, and to obtain a sputtering surface having a surface roughness average of from about 4 to about 32 microinches.

In one embodiment of a polishing method, the target 20 is placed on a lapping wheel 40 and the weight of the sputtering target 20, including the sputtering plate 22 and the backing plate 26, firmly presses the sputtering surface 24 against the flat polishing surface of the wheel 40. The lapping wheel 40 can be mounted on a stable, heavy mounting wheel 48 that minimizes vibration and chattering during rotation or oscillation of the wheel 40. As the target 20 and the lapping wheel 40 are pressed against each other and rotated, a polishing slurry of abrasive particles 42 is introduced between the two surfaces. The target 20 moves towards and is blocked by a pair of roller cylinders 50a,b which are held by a mounting plate 52. The polishing flatness of the sputtering surface 24 is controlled by the grain size of the abrasive particles. The abrasive particles can be particles of aluminum oxide, silicon carbide or even diamond particles. Preferably, a polishing slurry 42 of abrasive particles comprising diamond particles sized from about 2 to about 12 microns, for example 6 microns, is suspended in a medium such as deionized water. In one example, after polishing for about 30 minutes with a polishing slurry 42 comprising diamond particles sized 6 microns, the sputtering surface 24, when tested, had an X-ray diffraction peak at 38° having a FWHM that was reduced to about 0.48, which represents about a 30% improvement over the original FWHM value of 0.69.

While one type of polishing process is described, it should be understood that other polishing methods can also be used. For example, the sputtering surface 24 of the target 20 can also be polished in a lathe (not shown) using a suitable polishing or lapping tool affixed to the lathe while the substrate 20 is rotated about the axis of the lathe. Also, other versions of the polishing process can also be used, for example, the sputtering surface 24 of the target 20 can be maintained facing upward while it is polished by a polishing brush 47 pressed against the upward facing sputtering surface 24, as shown in FIG. 4B. In this version, the brush 47 and sputtering surface 24 are rotated or oscillated relative to one another while a polishing slurry 42 of diamond particles is added from a polishing slurry dispenser 44 containing a slurry supply 46.

In another polishing process version, an electrochemical polishing process is used in which a power supply 56 is used to apply a current to the sputtering surface 24 of the target 20 during polishing. The current can be applied through a first brush electrode 57 which contacts the target 20 and a second brush electrode 59 contacting the polishing slurry 42. A current of from about 5 to about 70 mAmps/cm² is applied to the target 20. In this version, the polishing slurry 42 is a conductive solution comprising a solution of an acid, such as HF acid, and mixtures of the same with other acids. Advantageously, the electrochemical polishing process provides better removal of the plastically deformed layer 32 because of application of the electric current as well as chemical and mechanical polishing.

In yet another version, an electropolishing apparatus 300 is used to remove the damaged surface layer 32 from the sputtering surface 24 of the target 20, as shown in FIG. 9. In the electropolishing process, the target 20 is immersed in an electrolytic solution 302 in an electropolishing cell 304. The electrolyte solution 302 can be an acidic solution, such as a dilute solution of HCl, HNO₃ or H₂SO₄, or mixtures thereof, depending on the target material. An electropolishing power supply 312 is used to apply a voltage to the sputtering target 20 which is used as an anode while a cathode 306 is also inserted in the solution 302. In one example, the sputtering surface 24 of a tantalum target 20 can be etched by application of a voltage of from about 5 to about 75 DC volts, for example about 50 volts. The electropolishing power supply 312 provides a current of up to 100 mAmps, for example, from about 5 to about 70 mAmps/cm², through the solution 302, the current value being based on the area of the sputtering surface 24 to be electropolished. In one example, the electrolytic solution 302 comprises an alcohol, for example, methanol or ethanol, with sulfuric acid added to the solution. The volumetric ratio of alcohol to acid can be from about 5:1 to about 40:1, for example, 20:1. Other acids such as HF acid can also be added to the electrolytic solution 302. For an anode comprising a tantalum target 20, the cathode 306 can be made from stainless steel, in the electropolishing apparatus 300. Also, preferably, the backside 29 of the target 20 is masked by a masking fixture 310, as shown, to protect the material of the backside 29 which can otherwise be eroded by the electrolytic solution 302.

In another version, which can be used with polishing the sputtering surface 24, or without polishing, the sputtering surface 24 of the sputtering target 20 is etched with an acidic etchant to remove the damaged layer 32. One method of etching the sputtering surface of the sputtering target comprises immersing the sputtering surface 24 of the target 20 in an acidic etchant 58 comprising a mixture of hydrofluoric acid and nitric acid. The hydrofluoric acid can have a concentration of from about 10% to about 52% by weight, for example, about 49.5 wt %. The nitric acid can have a concentration of from about 50% to about 80% by weight, for example, about 69.5 wt %. A suitable ratio of hydrofluoric acid to nitric acid is from about 15% to about 20% by volume. In one version, the acidic etchant 58 is provided in a tank 60 and the target 20 is dipped into the etchant 58, as for example, shown in FIG. 5. The acidic etchant 58 can be contained in the tank 60 which has a re-circulating pump, and optionally a filtration system (not shown), to remove residues from the acidic etchant 58. The acidic etchant 58 in the tank 60 can also be agitated, for example, by ultrasonic vibration provided by an ultrasonic vibrator (not shown) attached to a wall of the tank 60. Other stirring methods, including mechanical propeller stirring can also be used to stir the acidic etchant 58.

A fixture 68 can be used to hold the sputtering target 20 in contact with the acidic etchant 58 without exposing the backing plate 26 to the acidic fumes. A suitable fixture 68 comprises a base plate 70 and an annular clamping ring 72 affixed to the base plate by screws 74. The target 20 is placed on the base plate 70 and an annular clamping ring 72 is attached to the base plate with screws 74. The assembled fixture 68 is then flipped over so that the sputtering surface 24 of the sputtering plate 22 is exposed to the acidic etchant. An O-ring seal 76 seals off the backside surface 29 and backing plate 26 of the target 20 from the acidic etchant 58. The fixture 68 can be made from TEFLON™, polytetrafluoroethylene (PTFE), a polymer of fluorinated ethylene, from Dupont de Nemours Co., Delaware, or a high density polyurethane material. A polyurethane tube 78 can also be used to pass an inert gas such as argon or nitrogen to the backside surface 29 of the backing plate 26.

In one example, after chemical etching of the sputtering surface 24 in an acidic etchant 58 comprising HF and HNO₃, for about 30 minutes at room temperature, the FWHM of the (38°) peak of the sputtering surface 24 was reduced to about 0.49, which again represents about a 30% improvement over the original FWHM value of 0.69. In another example, after chemically etching of the sputtering surface 24 in an acidic etchant 58 comprising HF and HNO₃, for about 180 minutes at room temperature, the FWHM of the peak of the sputtering surface 24 reduces to about 0.46, which again represents about a 30% improvement over the original FWHM value of 0.69. Thus, chemically etching clearly removes the damaged layer 32 of the sputtering surface 24.

In another chemically etched version, the chemical etchant containing tank 60 is heated in a water bath 64, which in turn is heated by a heater 62, to maintain the temperature of the tank 60 at a temperature of at least about 50° C. It was determined that this temperature provided etching rates which were about 5 times faster than room temperature etching rates. The tank 60 can include a water bath 64 to maintain temperatures within a tight control, for example, plus or minus 2° C., to get optimal etching of the sputtering surface 24 of the target 20. Since the etching reaction is an exothermic reaction, it is desirable to precisely control the temperature of the acidic etchant 58 to prevent the etching reaction from proceeding too fast. The sputtering surface 24 of the target 20 is exposed to the acidic etchant for a time of from about 90 to about 180 minutes.

In yet another method, the sputtering surface 24 of the target 20 is initially lapped to achieve a surface roughness of from about 4 to about 32 microinches. Typically, the sputtering surface 24 is lapped to remove a thickness of at least about 25 microns, or more typically, from about 25 to about 300 microns. Thereafter, the sputtering surface 24 is chemically etched in the acidic etchant to remove an additional thickness of from about 25 to about 200 microns. The initial polishing process smoothens the sputtering surface 24 so that subsequently conducted chemically etching processes (that roughen the surface) result in a surface roughness level that is acceptable and provides consistent sputtering properties from the target 20 in a sputtering chamber 106. In one such example, the sputtering surface 24 was polished for about 15 minutes with a polishing slurry 42 comprising diamond particles sized 6 microns. Thereafter, the lapped target 20 was chemically etched in the aforementioned acidic etchant solution for about 60 minutes. The FWHM of the (38°) peak of the sputtering surface 24 is reduced to about 0.39, which represents about a 40% improvement over the original FWHM value of 0.69. In another example, the sputtering surface 24 was lapped polished for about 15 minutes with a polishing slurry comprising diamond particles sized about 6 microns. Thereafter, the lapped target 20 was chemically etched in the acidic etchant solution for about 120 minutes. The FWHM of the (55°) peak of the sputtering surface 24 of the target 20 was reduced to about 0.4.

A surface profilometer (not shown) can be used to measure surface roughness of the sputtering surface 24 of the sputtering plate 22, after polishing, etching, or any other surface treatment processes. The surface properties are beneficial to characterize the properties of the grains 28 on the sputtering surface 24. For example, surface roughness average, which is the mean of the absolute values of the displacements from the mean line of the peaks and valleys of the roughness features along the surface 24, can be used as a rough measure of the smoothness of the surface 24. An excessively rough surface is undesirable because it provides undesirable variability in the sputtering process. The surface profilometer typically comprises a stylus mounted on a surface-traversing arm which is connected to a column and driven by a motor. The stylus can be interchangeable with different versions available for different surface properties or measurements. The column is mounted on a stable base, such as a heavy metal or granite platform. The surface properties of the sputtering surface 24 are measured by dragging the stylus across an evaluation length of the surface 24. As the stylus moves up and down along the contact sputtering surface 24 it generates a surface profile signal trace of the fluctuations of the height of the asperities on the surface, which is passed to a transducer such as an inductive transducer to convert the vibrations of the stylus into a transducer signal, which is then processed by a computer. The selected sample length and signal trace are used to determine a set of surface profile numbers corresponding to different locations of the surface, and to also provide a visual surface profile trace on a display. A suitable surface profiler is a Form Talysurf Model 120 stylus profiler, from Taylor Hobson, Leicester, England. A scanning electron microscope that uses an electron beam reflected from the surface 24 to generate an image of the surface can also be used. In one measurement method, a sputtering plate 22 is cut into coupons and a plurality of measurements made on each coupon. The surface roughness measurements are then averaged to determine an average value for the surface 24. In one embodiment, three coupons were used and four surface profile traces of the changes in the heights of the roughness peaks and valleys were made for each coupon. In one version, it was determined that a suitable roughness average value was for example, from about 4 to about 32 microinches. The international standard ANSI/ASME B.46.1-1995 specifying appropriate cut-off lengths and evaluation lengths, was used to make these measurements.

In yet another embodiment, the sputtering surface 24 of the target is heated using an energy source such as a laser beam or lamp. The characteristics of the energy source, such as focal length, beam shape and beam diameter, are set to selectively heat the damaged surface later 32 of the sputtering surface 24 to a temperature sufficiently high to anneal the grains 28. In one embodiment, the energy source is used to heat the sputtering surface 24 to a depth thickness of less than 300 microns, and more typically less than 200 microns. For example, a focused laser beam can be used to selectively heat the localized surface 24 of the sputtering plate 22 to a temperature sufficiently high to reduce the density of dislocations in the damaged layer 32, without excessively increasing the bulk temperature of the entire target 20. A suitable temperature to reduce dislocations is at least about 400° C. Typically, the annealing temperature is less than about ⅔^{rd} of the melting point of the material of the sputtering surface 24. For example, the temperature can be about 400° C. to about 1000° C. As another example, a suitable temperature is about 600° C. for a sputtering surface 24 comprising tantalum which has a melting temperature of about 3017° C. The localized heat energy supplied to the damaged surface layer 32 of the sputtering surface 22 by the laser causes softening and fluxing of the localized heated region causing the dislocations in the layer 32 to move in the grains to reduce mechanical damage and strain. After heating of the damaged surface layer 32 of the sputtering surface 24 to anneal the same, rapid quenching occurs simply by conduction of heat out of the surface into the ambient environment.

Annealing of the grains in the sputtering surface 24 of the sputtering plate 22 can be performed using a laser annealing apparatus 80, an exemplary embodiment of which is shown in FIG. 6. The laser annealing apparatus 80 comprises a laser 82 in a laser beam enclosure 84. The laser 82 is powered and controlled by a controller 86 and can also include a scanning mechanism 88 to scan the laser beam 90 across the sputtering surface 24. Suitable lasers 82 can be used include, for example, Ar, CO₂ and KrF lasers. An argon laser transmits in the visible wavelength at about 5145 angstroms. A CO₂ laser is an infra-red energy source having a wavelength of 10.6 μm, and can provide beams having a power of the order of 10 kilowatts. The CO₂ laser is 100× more efficient than the argon laser and is of greater intensity, allowing faster scan speeds and larger spot sizes than the argon laser. Yet another type of laser is a KrF excimer laser having a wavelength of about 248 nm, an Eg of 5.0 eV, an efficiency of about 3%, and an output energy of 350 mJ. The laser beam 90 is typically a circular beam having a beam diameter of typically less than about 10 mm, and more typically from about 0.5 mm to about 4 mm. Suitable laser beams 90 can have wavelengths of from about 190 nm to about 10,600 nm. The laser 82 is typically operated at a power level of from about 50 Watts to about 2000 Watts.

While a laser beam heat treatment is described as an exemplary annealing process, other surface annealing processes can also be used. For example, alternative annealing processes include rapid thermal annealing systems which use a set of lamps, such as quartz lamps, to heat the sputtering surface 24 of the target 20. In one version, the annealing process is conducted by heating the sputtering surface 24 by directing infra-red radiation onto the sputtering surface 24 of the target 20, for example, via a set of quartz lamps mounted overhead the target 20 in a rapid thermal annealing chamber. The target 20 can also be heated by placing a heater such as a resistive heater adjacent to the target or by placing the target in a furnace. The radiant heat energy rapidly heats the sputtering surface 24 to re-orient and/or re-grow the plastically deformed crystalline grains 28 in the surface 24. The radiant energy can also be scanned across the surface 24 of the target 20 to provide the desired heat treatment. Yet other heating methods and systems include, plasma jet heating, electrical arc heating and flame heating. Thus, the scope of the present invention should not be limited to the exemplary versions described herein, and the invention includes other localized surface annealing processes and apparatus as would be apparent to those of ordinary skill in the art.

The annealing process can also be used in combination with the other processes described herein. In one example, after machining of a target 20, the sputtering surface 24 of the target 20 is polished using a polishing process. The polishing process is followed by etching the sputtering surface 24 of the target 20 in an acidic etchant 58 as described. Thereafter, the sputtering surface 24 of the target 20 is annealed by heating it to a temperature of from about 400° C. to 1000° C. The combination of polishing, etching and annealing, is expected to provide a target 20 having a lower defect count and less damaged surface grains 28.

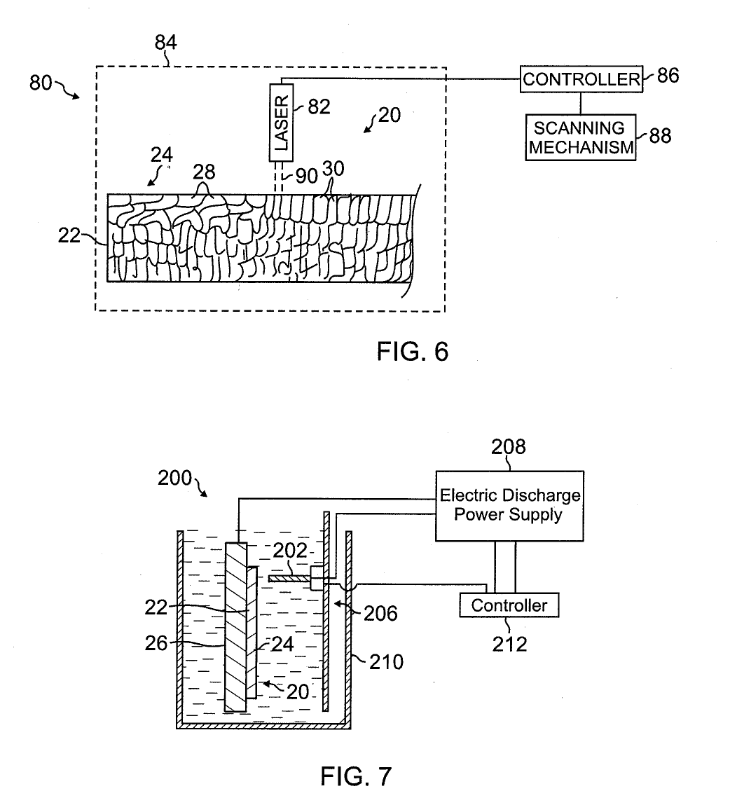

In another method, commonly known as electric discharge machining (EDM) the layer of plastically deformed grains on the sputtering surface 24 can be removed by electrical discharges. In a typical EDM apparatus 200, as shown in FIG. 7, high-frequency electrical spark discharges from an electrode 202 are used to disintegrate the electrically conductive material of the sputtering surface 24 to remove a layer of the sputtering plate 22 which has the plastically deformed grains 28. In this prospective example, the electrode 202 and sputtering surface 24 are immersed in a dielectric material 204 in a tank 210, and an electrode moving mechanism 206 is used to maintain a spark gap of from about 0.013 to about 0.5 mm, between the electrode 202 and the target 20. The electrode moving mechanism 206 can be a screw thread or hydraulic cylinder, which is used for moving the electrode 202 vertically up and down across the surface 24 and also to set the gap size between the electrode 202 and the sputtering surface 24. The electrical spark formed in the gap melts or vaporize small particles of the target 20 which are flushed away as the electrode 202 advances across the surface 24. The electrode 202 uses electrical discharges to remove material from the sputtering surface 24, with each spark producing a temperature of between 10,000 to 20,000° C. As the electrode 202 is moved across the sputtering surface, the resultant electrical arcs erode away a portion of the sputtering surface 24. In one version, the electrode 202 is a metal wire comprising for example, Al, Cr, Cr/Ni, Cu/Co, Cu/Mn, Cu/Sn, Cu/W, Ni, Ni/Co, Ni/Fe, Ni/Mn, Ni/Si, Ti, Ti/Al, TiC/Ni, W/CrC/Cu or WC/Co, of which a copper wire is typically used. EDM can use die-sinking which uses a machined graphite or copper electrode to burn a desired shape into the sputtering plate 22, or electrode wire cutting which uses a very thin wire to cut-off the damaged portion of the sputtering surface 24.

In the EDM process, an electric discharge power supply 208 maintains the electrode 202 at a negative polarity while a more positive polarity is applied to the sputtering plate 22 at, for example, voltages of from about 100 to about 400 Volts. A controller 212 controls the power supply 208 to apply short pulsed currents to the electrode 202 at steady repetitive intervals while also controlling the electrode moving mechanism 206 to move the electrode 202 across the sputtering surface 24. The power supply 208 can comprise a pulsed current generating power unit which controls generated current to form pulses. For example, the power supply 208 can generate pulses of a 1000 Amp current at intervals of less than one microsecond during the electric discharge process. In finish machining, the pulses can be set to nanosecond duration levels to generate shorter pulsed currents steadily and repetitively.

In one version, after pre-conditioning, the sputtering target 20 can be used in a sputtering chamber 106, an embodiment of which is shown in FIG. 8, to sputter deposit a layer such as one or more of tantalum, tantalum nitride, aluminum, aluminum nitride, titanium, titanium nitride, tungsten, tungsten nitride and copper, onto a substrate 104. A substrate support 108 is provided for supporting the substrate 104 in the chamber 106. The substrate 104 is introduced into the chamber 106 through a substrate loading inlet (not shown) in a sidewall of the chamber 106 and placed on the support 108. The support 108 can be lifted or lowered by support lift bellows (not shown).

A sputtering gas supply 103 introduces sputtering gas into the chamber 106 to maintain the sputtering gas at a sub atmospheric pressure in the process zone 109. The sputtering gas is introduced into the chamber 106 through a gas inlet 133 that is connected via the gas inputs 125a,b to one or more gas sources 124, 127, respectively. One or more mass flow controllers 126 are used to control the flow rate of the individual gases, which may be premixed in a mixing manifold 131 prior to their introduction into the chamber 106 or which may be separately introduced into the chamber 106. The sputtering gas typically includes a non-reactive gas, such as argon or xenon, which when energized to form a plasma, energetically impinges upon and bombards the target 20 to sputter material off from the target 20. The sputtering gas may also comprise a reactive gas, such as nitrogen. Also, other compositions of sputtering gas that include other reactive gases or other types of non-reactive gases, may be used as would be apparent to one of ordinary skill in the art.

An exhaust system 128 controls the pressure of the sputtering gas in the chamber 106 and exhausts excess gas and by-product gases from the chamber 106. The exhaust system 128 comprises an exhaust port 129 in the chamber 106 that is connected to an exhaust line 134 that leads to one or more exhaust pumps 139. A throttle valve 137 in the exhaust line 134 may be used to control the pressure of the sputtering gas in the chamber 106. Typically, the pressure of the sputtering gas in the chamber 106 is set to sub-atmospheric levels.

The sputtering chamber 106 comprises a sputtering target 20 facing the substrate 104 to deposit material on the substrate 104. The sputtering chamber 106 may also have a shield 120 to protect a wall 112 of the chamber 106 from sputtered material, and which may also serve as grounding plane. The target 20 can be electrically isolated from the chamber 106 and is connected to a power source 122, such as a DC or RF power source. In one version, the power source 122, target 20, and shield 120 operate as a gas energizer 190 capable of energizing the sputtering gas to sputter material from the target 20. The power source 122 can electrically bias the target 20 relative to the shield 120 to energize the sputtering gas in the chamber 106 to form a plasma that sputters material from the target 20. The material sputtered from the target 20 by the plasma is deposited on the substrate 104 and may also react with gas components of the plasma to form a sputter deposition layer on the substrate 104.

The chamber 106 can further comprise a magnetic field generator 135 that generates a magnetic field 105 near the target 20 to increase an ion density in a high-density plasma region 138 adjacent to the target 20 to improve the sputtering of the target material. In addition, an improved magnetic field generator 135 may be used to allow sustained self-sputtering of copper or sputtering of aluminum, titanium, or other metals; while minimizing the need for non-reactive gases for target bombardment purposes, as for example, described in U.S. Pat. No. 6,183,614 to Fu, entitled “Rotating Sputter Magnetron Assembly”; and U.S. Pat. No. 6,274,008 to Gopalraja et al., entitled “Integrated Process for Copper Via Filling,” both of which are incorporated herein by reference in their entirety. In one version, the magnetic field generator 135 generates a semi-toroidal magnetic field at the target 20. In another version, the magnetic field generator 135 comprises a motor 306 to rotate the magnetic field generator 135 about a rotation axis.

The chamber 106 can be controlled by the chamber controller 54, which comprises program code having instruction sets to operate components of the chamber 106 to process substrates 104 in the chamber 106. For example, the controller 54 can comprise a substrate positioning instruction set to operate one or more of the substrate support 108 and substrate transport to position a substrate 104 in the chamber 106; a gas flow control instruction set to operate the sputtering gas supply 103 and mass flow controllers 126; a gas pressure control instruction set to operate the exhaust system 128 and throttle valve 137 to maintain a pressure in the chamber 106; a gas energizer control instruction set to operate the gas energizer 190 to set a gas energizing power level; a temperature control instruction set to control temperatures in the chamber 106; and a process monitoring instruction set to monitor the process in the chamber 106.

Any sputtering process can be used with the sputtering target 20 of the present invention. Exemplary sputtering processes are described in U.S. Pat. No. 3,616,402 to Kumagai, entitled “Sputtering Method and Apparatus”; U.S. Pat. No. 3,617,463 to Gregor at. al., entitled “Apparatus and Method for Sputter Etching”; U.S. Pat. No. 4,450,062 to Macaulay et. al., entitled “Sputtering Apparatus and Method”; U.S. Pat. No. 5,209,835 to Makino et. al., entitled “Method for Producing a Specified Zirconium-Silicon Amorphous Oxide Film Composition by Sputtering”; U.S. Pat. No. 5,175,608 to Nihei et. al. entitled “Method of and Apparatus for Sputtering and Integrated Circuit Device”; and U.S. Pat. No. 5,160,534 to Hiraki et. al. entitled “Titanium-Tungsten Target Material for Sputtering and Manufacturing Method Therefor”, all of which are incorporated herein by this reference.

Although exemplary embodiments of the present invention are shown and described, those of ordinary skill in the art may devise other embodiments which incorporate the present invention, and which are also within the scope of the present invention. For example, the target 20 may comprise materials other than the exemplary ones described herein and additional treatment steps can also be performed on the target 20. Also, a target 20 having different shapes, or different compositions, other than those specifically described can be treated. Furthermore, relative or positional terms shown with respect to the exemplary embodiments are interchangeable. Therefore, the appended claims should not be limited to the descriptions of the preferred versions, materials, or spatial arrangements described herein to illustrate the invention.

What is claimed is:

1. A method of pre-conditioning a sputtering target prior to use of the target in a sputtering process, the method comprising:
(a) providing a sputtering target having a sputtering surface with a damaged surface layer; and
(b) polishing the sputtering surface of the sputtering target to remove a thickness of at least about 25 microns, and to obtain a sputtering surface having a surface roughness average of from about 4 to about 32 microinches.

2. A method according to claim 1 wherein (b) comprises electrochemical polishing in which a current is applied to the sputtering surface of the target during the polishing process.

3. A method according to claim 2 comprising applying a current of from about 5 to about 70 mAmps/cm².

4. A method according to claim 1 wherein (b) comprises pressing the sputtering surface against a lapping wheel under its own weight while applying a polishing slurry between the plate and the sputtering surface.

5. A method according to claim 4 comprising providing a polishing slurry comprising diamond powder in deionized water.

6. A method according to claim 5 wherein the diamond particles are sized from about 2 to about 15 microns.

7. A method according to claim 1 wherein in (b), the sputtering surface of the sputtering target is positioned facing upward and is polished by a polishing brush which is pressed against the upward facing sputtering surface.

8. A method according to claim 1 comprising after (b), etching the sputtering surface of the sputtering target by electrochemical polishing.

9. A method according to claim 1 comprising after (b), etching the sputtering surface of the sputtering target with an acidic etchant.

10. A method according to claim 9 wherein the acidic etchant comprises hydrofluoric acid and nitric acid.

11. A method according to claim 10 wherein the hydrofluoric acid comprises a concentration of from about 10% to about 52% by weight.

12. A method according to claim 10 wherein the nitric acid comprises a concentration of from about 50% to about 80% by weight.

13. A method according to claim 10 wherein the ratio of hydrofluoric acid to nitric acid is from about 10% to about 20% by volume.

14. A method according to claim 1 further comprising, after (b),
(i) etching the sputtering surface of the sputtering target with an acidic etchant; and
(ii) heating the sputtering surface to a temperature of from about 400° C. to about 1000° C.

15. A method according to claim 1 comprising providing a target comprising a sputtering surface composed of titanium, tantalum or tungsten.

16. A method according to claim 15 wherein the sputtering target comprises (i) a sputtering disc having a diameter from about 200 to about 500 mm, and a thickness from 2.5 to about 25 mm, and (ii) a backing plate comprising a copper-zinc alloy.

17. A method according to claim 1 further comprising:
(1) mounting the sputtering target in a sputtering zone;
(2) placing a substrate proximate to the target in the sputtering zone; and
(3) forming a plasma to sputter material from the sputtering target onto the substrate.

18. A method of pre-conditioning a sputtering target prior to use of the target in a sputtering process, the method comprising:
(a) providing a sputtering target having a sputtering surface with a damaged surface layer; and
(b) etching the sputtering surface of the sputtering target in an acidic etchant comprising hydrofluoric acid and nitric acid, the hydrofluoric acid comprising a concentration of from about 30% to about 52% by weight, the nitric acid comprising a concentration of from about 50% to about 80% by weight, and the ratio of hydrofluoric acid to nitric acid being from about 10% to about 20% by volume.

19. A method according to claim 18 further comprising electropolishing the sputtering surface of the sputtering target by exposing the sputtering surface to an electrolytic solution while applying a current through the electrolytic solution.

20. A method according to claim 19 comprising applying a current of through the electrolytic solution of from about 5 to about 70 mAmps/cm².

21. A method according to claim 18 further comprising electrochemical polishing of the sputtering surface.

22. A method according to claim 18 further comprising polishing the sputtering surface by pressing the sputtering surface against a lapping wheel under its own weight while applying a polishing slurry to the wheel.

23. A method of pre-conditioning a sputtering target prior to use of the target in a sputtering process, the method comprising:
(a) providing a sputtering target having a sputtering surface with a damaged surface layer; and
(b) heating the damaged surface layer of the sputtering surface to a temperature that is at least about 400° C.

24. A method according to claim 23 comprising heating the sputtering surface to a temperature of less than about ⅔^{rd} of the melting point of the material of the sputtering surface.

25. A method according to claim 23 comprising heating the sputtering surface to a temperature of less than about 1000° C.

26. A method according to claim 23 comprising heating the sputtering surface to a depth thickness of less than 300 microns.

27. A method according to claim 23 comprising heating the sputtering surface with a laser beam.

28. A method according to claim 23 comprising heating the sputtering surface with a set of quartz lamps.

29. A method of pre-conditioning a sputtering target prior to use of the target in a sputtering process, the method comprising:
(a) providing a sputtering target having a sputtering surface with a damaged surface layer; and
(b) maintaining an electrode at a gap distance from the sputtering surface; and
(c) applying a pulsed current to the electrode to form electrical arcs between the electrode and the sputtering surface to substantially remove the damaged surface layer of the sputtering surface.

30. A method of pre-conditioning a sputtering target prior to use of the target in a sputtering process, the method comprising:
(a) immersing a sputtering surface of a sputtering target into an electrolytic solution, the sputtering surface having a damaged surface layer; and
(b) applying a current through the electrolytic solution to remove the damaged surface layer of the sputtering surface.

31. A method according to claim 30 comprising applying a current of through the electrolytic solution of from about 5 to about 70 mAmps/cm².

32. A method according to claim 30 comprising immersing the sputtering surface in an electrolytic solution comprising a dilute solution of HCl, HNO₃, H₂SO₄ or mixtures thereof.

33. A method according to claim 30 comprising applying a DC voltage across the target and an electrode in the electrolytic solution, the DC voltage being from about 5 to about 75 volts.
